(19) United States
(12) Patent Application Publication
(10) Pub. No.: US 2026/0119728 A1
(43) Pub. Date: Apr. 30, 2026

(54) THREE-DIMENSIONAL SCENE CONSTRUCTION METHOD AND THREE-DIMENSIONAL SCENE CONSTRUCTION APPARATUS

(71) Applicant: Wistron Corporation, New Taipei City (TW)

(72) Inventors: Cheng Chan Cheng, New Taipei City (TW); Chong Rui Li, New Taipei City (TW); Yanan Yen, New Taipei City (TW)

(73) Assignee: Wistron Corporation, New Taipei City (TW)

(21) Appl. No.: 18/973,106

(22) Filed: Dec. 9, 2024

(30) Foreign Application Priority Data
Oct. 30, 2024 (TW) 113141712

(51) Int. Cl. G06F 30/13

(52) U.S. Cl. CPC G06F 30/13

(57) ABSTRACT

A three-dimensional scene construction method and a three-dimensional scene construction apparatus are provided. One or more target objects are identified in a plan configuration image, where the plan configuration image corresponds to a plan view having an outline of the target object. One or more corresponding three-dimensional objects are added in the three-dimensional space according to the position and shape of the target object in the plane configuration image. Therefore, the efficiency and accuracy of model construction could be improved.

This application claims the priority benefit of Taiwan application serial no. 113141712, filed on Oct. 30, 2024. The entirety of the above-mentioned patent application is hereby incorporated by reference herein and made a part of this specification.

### BACKGROUND OF THE DISCLOSURE

### 1. Field of the Disclosure

The present disclosure relates to a three-dimensional building technology, and particularly relates to a three-dimensional scene building method and a three-dimensional scene building device.

### 2. Description of Related Art

Before planning the workflow in a factory, engineers usually build a three-dimensional (3D) model of the entire manufacturing line using simulation software. This allows them to simulate manufacturing scenarios under different parameters and conditions, and analyze the collected data. Simulation software (for example, the Omniverse platform) mostly presents in 3D form, enabling engineers to clearly observe the placement of objects, the movement of personnel, and potential congestions, thereby gaining a deeper understanding of how the manufacturing line operates in a virtual factory.

In the past, building a virtual factory required a series of preliminary operations, which included creating 3D virtual equipment in the virtual scene. Therefore, engineers had to configure the initial factory layout according to the design draft. If only a small number of equipment needed to be placed, it may not consume too much time and effort. However, if it involved hundreds of equipment or the integration of multiple factories, the time required for building would double.

### SUMMARY OF THE DISCLOSURE

Accordingly, the present disclosure is directed to a three-dimensional scene building method and a three-dimensional scene building device, which may improve the efficiency of virtual scene building.

The three-dimensional scene building method of the present disclosure embodiment is implemented through a processor. The three-dimensional scene building method includes, but is not limited to, the following steps: identifying one or more target objects in a plane configuration image, wherein the plane configuration image corresponds to a floor plan with contours of the target objects; and adding one or more corresponding three-dimensional objects in the three-dimensional space based on the position and shape of the target objects in the plane configuration image.

The three-dimensional scene building device of the present disclosure embodiment includes, but is not limited to, a memory and a processor. The memory stores program code. The processor is coupled to the memory. The processor loads the program code and executes: identifying one or more target objects in a plane configuration image, wherein the plane configuration image corresponds to a floor plan with contours of the target objects; and adding one or more corresponding three-dimensional objects in the three-dimensional space based on the position and shape of the target objects in the plane configuration image.

Based on the above, the three-dimensional scene building method and the three-dimensional scene building device of the present disclosure embodiment may identify target objects from the plane configuration image, and add three-dimensional objects corresponding to the target objects into the three-dimensional space. By this means, it may rapidly realize the engineer's design concept without the need for time-consuming drawing by professional three-dimensional art personnel, thereby saving time and cost.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a component block diagram of a three-dimensional scene building device according to an embodiment of the present disclosure.

FIG. 2 is a flowchart of a three-dimensional scene building method according to an embodiment of the present disclosure.

FIG. 3 is a schematic diagram of a plane configuration image according to an embodiment of the present disclosure.

FIG. 4A is a schematic diagram of an equipment candidate list according to an embodiment of the present disclosure.

FIG. 4B is a schematic diagram of classification results according to an embodiment of the present disclosure.

FIG. 5A is a schematic diagram of an equipment candidate list according to an embodiment of the present disclosure.

FIG. 5B is a schematic diagram of classification results according to an embodiment of the present disclosure.

FIG. 6A is a schematic diagram of a feature space according to an embodiment of the present disclosure.

FIG. 6B is a schematic diagram of classification results according to an embodiment of the present disclosure.

FIG. 7 is a schematic diagram of a first virtual scene according to an embodiment of the present disclosure.

FIG. 8A is a schematic diagram of a three-dimensional object according to an embodiment of the present disclosure.

FIG. 8B is a schematic diagram of a second virtual scene according to an embodiment of the present disclosure.

### DESCRIPTION OF THE EMBODIMENTS

Reference would now be made in detail to the present preferred embodiments of the disclosure, examples of which are illustrated in the accompanying drawings. Wherever possible, the same reference numbers are used in the drawings and the description to refer to the same or like parts.

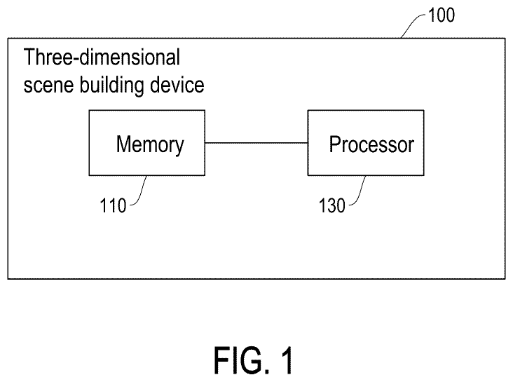

FIG. 1 is a component block diagram of a three-dimensional scene building device 100 according to an embodiment of the present disclosure. Refer to FIG. 1, the three-dimensional scene building device 100 includes (but is not limited to) a memory 110 and a processor 130. The three-dimensional scene building device 100 may be a mobile phone, tablet computer, laptop computer, desktop computer, server, voice assistant device, smart home appliance, wearable device, or other electronic device.

The memory 110 may be any type of fixed or removable random access memory (RAM), read-only memory (ROM), flash memory, conventional hard disk drive (HDD), solid-state drive (SSD), or similar component. In one embodiment, the memory 110 is used to store program code, software modules, configurations, data (e.g., images, object parameters, or three-dimensional space parameters), or files, which would be described in detail in subsequent embodiments.

The processor 130 is coupled to the memory 110. The processor 130 may be a central processing unit (CPU), graphic processing unit (GPU), or other programmable general-purpose or special-purpose microprocessor, digital signal processor (DSP), programmable controller, field programmable gate array (FPGA), application-specific integrated circuit (ASIC), neural network accelerator, or other similar components or a combination of the above components. In one embodiment, the processor 130 is used to execute all or part of the operations of the three-dimensional scene building device 100, and may load and execute various program codes, software modules, files, and data stored in the memory 110.

In the following, the method described in the embodiments of the present disclosure would be explained in conjunction with various devices, components, and modules in the three-dimensional scene building device 100. The steps of this method may be adjusted consequently according to the implementation circumstances and are not limited to this.

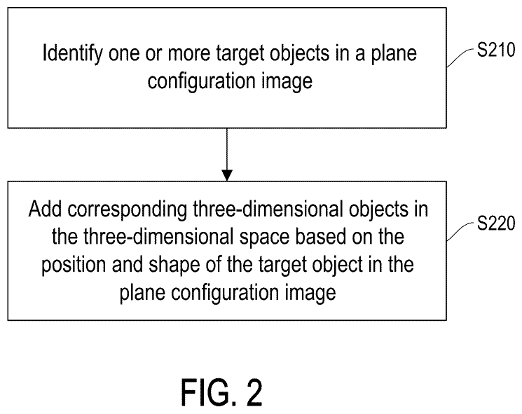

FIG. 2 is a flowchart of a three-dimensional scene building method according to an embodiment of the present disclosure. Refer to FIG. 2, the processor 130 identifies one or more target objects in a plane configuration image (Step S210). Specifically, the plane configuration image corresponds to a floor plan with contours of one or more target objects. The floor plan is a planar structural diagram of a building from a top view. The plane configuration image is in image format, and its image content is a floor plan configuring one or more target objects. The target object is an object defined by plane drawing software, computer-aided design (CAD) software, or design software. The target object corresponds to an actual, imaginary, or planned existing object. The target object may be a structural object, equipment object, human object, furniture object, electrical appliance object, or other types of objects. That is, the object type of the target object may be structure, equipment, human, furniture, electrical appliance, or other types. The structural object, for example, corresponds to walls, doors, pillars, beams, or windows. Based on different application requirements, the equipment corresponding to the equipment object may be applicable to factories, offices, homes, schools, or other environments. For factories, the equipment object may correspond to process equipment, but is not limited to this. The human object corresponds to various types of people, the furniture object corresponds to various types of furniture, and the electrical appliance object corresponds to various types of electrical appliances. It should be noted that the object type of the target object may still be changed according to actual requirements.

In one embodiment, the target objects in the floor plan may be presented as geometric shapes, irregular shapes, or contours of the target objects from the top view. For example, the target object may be a rectangle, but is not limited to this. Furthermore, the shape of the target object in the floor plan is defined by lines. For instance, the lines enclose a representative shape of the target object from the top view. The lines of specific target objects may be in specific colors. For example, the structural object may be represented by blue lines, and the equipment object may be represented by black lines, but this is not limited to these colors.

In one embodiment, the target objects in the floor plan are also defined with identification information. The identification information is used to represent the type, model, or other identifiers of the target object. Taking a factory application scenario as an example, the identification information may be in the form of text, symbols, or patterns representing process equipment, workbenches, or manufacturing lines.

In one embodiment, the processor 130 converts the engineering drawing to a floor plan configuration image. The engineering drawing is generated by adding shapes corresponding to one or more target objects to the floor plan through drawing software, computer-aided design software, or design software. The engineering drawing may be, for example, a computer-aided design related file. The floor plan configuration image may be a PNG or JPEG or other image type picture (also known as a two-dimensional image). For the conversion operation, the processor 130 may upload the engineering drawing to a conversion-related cloud server, or convert it through computer-aided design software or a conversion program.

In one embodiment, the processor 130 may identify one or more target objects based on the colors of the one or more target objects in the floor plan configuration image. The processor 130 may define color threshold values based on the colors of the target objects in the floor plan configuration image, so that target objects formed by lines of the same or similar colors correspond to specific object types. Taking structural objects as an example of target objects, if the color threshold value corresponding to structural objects is 2 to 254 (i.e., corresponding to a color range), then target objects with thin lines that are not black may be filtered out.

In one embodiment, in the process of identifying object types based on color, the processor 130 may perform binarization processing on the floor plan configuration image. This binarization processing uses a classification threshold value (as a color threshold value) defined based on the grayscale value of the structural object. In the binarization processing, in response to the grayscale value being greater than (or not less than) the classification threshold value, the new grayscale value would be set to the maximum value (for example, 255), and in response to the grayscale value being less than (or not greater than) the classification threshold value, the new grayscale value would be set to the minimum value (for example, 1). In other words, the grayscale values of pixels in the image after binarization processing are only one of the maximum value or the minimum value. The classification threshold value may be, for example, the same as the grayscale value of the lines of the structural object in the floor plan configuration image. Consequently, the new grayscale value of the lines of the structural object would be one of the maximum value or the minimum value. The processor 130 may further exclude other target objects with new grayscale values different from the lines of the structural object from the candidate list of structural objects (also known as the structural candidate list).

In one embodiment, the processor 130 may identify one or more target objects based on the shapes of the one or more target objects. The processor 130, drawing software, computer-aided design software, or design software may pre-define the shapes of target objects in the engineering drawing or floor plan. As mentioned earlier, the target objects in the floor plan may be presented as geometric shapes, irregular shapes, or contours of the target objects from the top view. Therefore, the shapes of target objects may be used to distinguish the types of target objects.

In one embodiment, the shape of the structural object corresponds to its length and width. The processor 130 may decide that the length of the structural object is greater than a lower length limit. The lower length limit is the minimum length of this structural object from the top view in the real scene. Taking a wall as an example of a structural object, its lower length limit is 100 centimeters. Assuming the dimensions of the factory in the floor plan are 4582 centimeters (cm)×2410 centimeters (cm), and the engineering drawing of the factory is mapped to a PNG image (for example, with dimensions of 15000 pixels×15000 pixels), a 100-centimeter (i.e., 1-meter) wall is mapped to approximately 100 pixels, which is equivalent to 1 pixel corresponding to 1 centimeter. Therefore, target objects with lengths less than 100 centimeters or 100 pixels would be excluded from the candidate list of structural objects (i.e., prohibited from/not included in the candidate list of structural objects). On the other hand, target objects with lengths greater than 100 centimeters or 100 pixels would be included in the candidate list of structural objects.

Moreover, the processor 130 may decide that the width of the structural object is within a first width range. The first width range is the range of allowable widths for this structural object from the top view in the real scene. Taking a wall as an example of a structural object, the wall thickness typically falls within 15˜25 centimeters (i.e., 0.15 meters˜0.25 meters), which is approximately equivalent to 15˜25 pixels. Therefore, target objects with widths (e.g., the distance between two lines) outside the range of 15 pixels to 25 pixels would be excluded from the candidate list of structural objects (i.e., prohibited from/not included in the candidate list of structural objects). On the other hand, target objects with widths (e.g., the distance between two lines) between 15 pixels and 25 pixels would be included in the candidate list of structural objects.

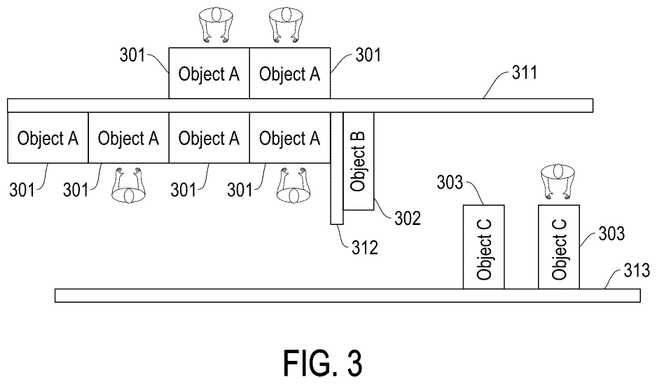

For example, FIG. 3 is a schematic diagram of a floor plan configuration image according to an embodiment of the present disclosure. Referring to FIG. 3, objects 301, 302, 303 and wall objects 311, 312, 313 are located in the floor plan configuration image. The lengths of objects 301, 302, 303 are all less than 100 pixels (i.e., the lower length limit), therefore objects 301, 302, 303 are excluded from the candidate list of structural objects. The lengths of wall objects 311, 312, 313 are all greater than 100 pixels, thus the processor 130 includes wall objects 311, 312, 313 in the candidate list of structural objects. Subsequently, the widths of wall objects 311, 312, 313 are all between 15 pixels and 25 pixels (i.e., the first width range), therefore, the processor 130 includes wall objects 311, 312, 313 in the candidate list of structural objects. Finally, the processor 130 confirms that the wall objects 311, 312, 313 in the candidate list of structural objects are all structural objects.

In one embodiment, the pixel-to-length mapping table may be as follows:

TABLE (1)

| Map Pixels | How many pixels approximately |
|---|---|
| (count) | map to 1 meter |
| 1250 | 12 |
| 2500 | 25 |
| 5000 | 50 |
| 10000 | 75 |
| 15000 | 100 |

Assuming the minimum mapping pixels of the floor plan configuration image is 1250 pixels×1250 pixels, 1 meter is approximately mapped to 12 pixels. Therefore, if the minimum mapping pixels are used, the lower length limit corresponding to the minimum length of 1 meter is 12 pixels, and the first width range corresponding to 0.2 meters is greater than or equal to 2 pixels. However, the lower the resolution of the floor plan configuration image, the lower the recognition, so the mapping pixels may be 10000 to 15000 pixels.

It should be noted that for structural objects, the order of comparison may sequentially include color threshold, lower length limit, and first width range, but the order is not limited to this.

In one embodiment, taking equipment objects as an example of target objects, assuming the color threshold value corresponding to equipment objects is 254 and the lines of structural objects or other objects are black, then thin black lines of equipment objects could be selected, and structural objects with black lines could be excluded. However, the target objects and their corresponding color threshold values or line colors may still be changed based on actual requirements.

In one embodiment, the shape of the equipment object corresponds to its length and width. The processor 130 may decide that the length of the equipment object is within a length range, and decide that the width of the equipment object is within a second width range. Assume that the numerical value of the length of the target object is greater than the numerical value of the width. The length range is the range of allowable lengths for this equipment object from the top view in the real scene. The second width range is the range of allowable lengths for this equipment object from the top view in the real scene. Taking the shape of the equipment object in the floor plan as a rectangle as an example, an algorithm for finding the bounding matrix could be used. Target objects with lengths outside the length range would be excluded from the candidate list of equipment objects (also called the equipment candidate list) (i.e., prohibited/not included in the candidate list of equipment objects), and/or target objects with widths outside the second width range would be excluded from the candidate list of equipment objects (i.e., prohibited/not included in the candidate list of equipment objects). On the other hand, target objects with lengths within the length range would be included in the candidate list of equipment objects, and/or target objects with widths within the second width range would be included in the candidate list of equipment objects.

Taking workbenches or process equipment as examples of equipment objects, the (rectangular) length range is from 50 centimeters (e.g., corresponding to 0.02 times the length of the floor plan image) to 200 centimeters (e.g., corresponding to 0.1 times the length of the floor plan image), and the (rectangular) second width range is from 50 centimeters (e.g., corresponding to 0.02 times the length of the floor plan image) to 200 centimeters (e.g., corresponding to 0.1 times the length of the floor plan image). If the actual length corresponding to the floor plan image (corresponding to the factory) is 4580 centimeters, then the length of the equipment would not exceed 200 centimeters and would not be less than 50 centimeters, therefore the aforementioned length and width ranges may correspond to 0.02 to 0.1 times the length of the floor plan image. However, the length range, second width range, and shape corresponding to the equipment objects may still be changed based on actual requirements.

Taking FIG. 3 as an example, assume that wall objects 311, 312, 313 are excluded first. The lengths of object 301, object 302, and object 303 are all within the length range, and their widths are all within the second width range, therefore the processor 130 may include object 301, object 302, and object 303 in the candidate list of equipment objects. Finally, the processor 130 decides that object 301, object 302, and object 303 in the candidate list of equipment objects are all equipment objects.

In one embodiment, rectangles that meet the aforementioned length range and second width range may be repeated. The processor 130 may check whether there are rectangles corresponding to other equipment objects within the coordinate range of a rectangle of a target object to be evaluated. If there are rectangles corresponding to other equipment objects in this coordinate range, these rectangles of other equipment objects may be removed from the candidate list until there are no rectangles corresponding to any other equipment objects within the coordinate range. The processor 130 may then include this target object to be evaluated (or its corresponding rectangle) in the candidate list of rectangles (or equipment objects).

It should be explained that, for equipment objects, the order may be to compare the color threshold value, length range, and second width range sequentially, but the order is not limited to this.

Target objects of the same type may correspond to different identification information. For example, equipment objects may be defined with different names or numbers: workbench-0, workbench-1, workbench-2, process equipment-0, process equipment-1, and process equipment-2. Therefore, it is necessary to distinguish these target objects with different identification information.

In one embodiment, the equipment objects may have their identification information in the floor plan image. This identification information is used to represent the type, model, or other identifiers of the equipment objects. Taking the factory application scenario as an example, the identification information may be in the form of text, symbols, or patterns representing process equipment, workbenches, or manufacturing lines.

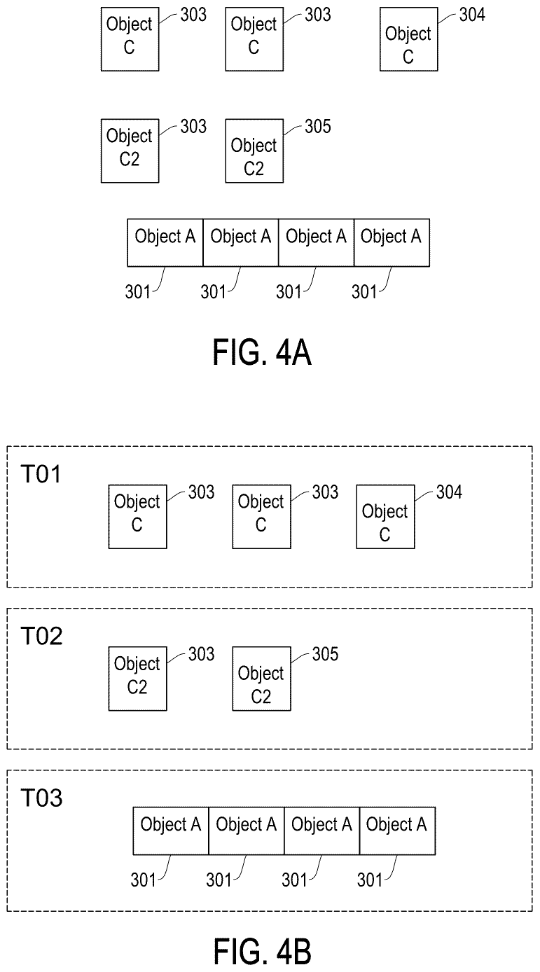

For example, FIG. 4A is a schematic diagram of an equipment candidate list (i.e., a candidate list of equipment objects) according to an embodiment of the present disclosure. Refer to FIG. 4A, the candidate list includes object 301 (with its identification information in text form as “Object A”), objects 303, 304 (with their identification information in text form as “Object C”), and objects 305, 306 (with their identification information in text form as “Object C2”). Taking a factory as an example for the identification information, “Object A” is a workbench, “Object C” is the first process equipment, and “Object C2” is the second process equipment.

The processor 130 may compare the identification information of an equipment object with the identification information of another equipment object to generate a comparison result. The comparison result includes whether the identification information of the equipment object is the same as the identification information of another equipment object (or whether the two equipment objects belong to the same equipment type), and whether the identification information of the equipment object is different from the identification information of another equipment object (or whether the two equipment objects do not belong to the same equipment type or belong to different equipment types). The processor 130 may decide the equipment type corresponding to the equipment object and another equipment object based on the comparison result. For example, in response to the identification information of the equipment object being the same as the identification information of another equipment object (or the two equipment objects belonging to the same equipment type), the processor 130 may map these two equipment objects to the same equipment type. In response to the identification information of the equipment object being different from the identification information of another equipment object (or the two equipment objects not belonging to the same equipment type or belonging to different equipment types), the processor 130 may map these two equipment objects to different equipment types.

In one embodiment, the processor 130 may compare the identification information of the equipment object with that of another equipment object in the floor plan image to generate a comparison result. The comparison result corresponds to image similarity. As shown in FIG. 4A, for the identification information of “Object C”, the identification information of object 303 and object 304 have different positions within the rectangular frames. Alternatively, for the identification information of “Object C2”, the identification information of object 305 and object 306 have different positions within the rectangular frames.

The processor 130 may segment/crop the image area corresponding to the identification information from the floor plan image. For two equipment objects, the processor 130 may compare the pixel positions occupied by the identification information in the corresponding two image areas. For example, whether both image areas have identification information at the pixel coordinates (1,1). The processor 130 may determine the number of pixels that have identification information at the same pixel coordinates in both image areas, or the proportion of this pixel number to the total number of pixels in one image area, compare this pixel number or proportion with a corresponding threshold value, and generate a comparison result based on this.

For example, FIG. 4B is a schematic diagram of classification results according to an embodiment of the disclosure. Refer to FIG. 4A and FIG. 4B, the proportion of pixels that have identification information at the same pixel coordinates between the image area corresponding to “Object A” of object 301 and the image area corresponding to “Object A” of another object 301 is 100%, and the corresponding threshold value is 99%, therefore the comparison result indicates that the two objects 301 correspond to the same equipment type. The proportion of pixels that have identification information at the same pixel coordinates between the image area corresponding to “Object C” of object 303 and the image area corresponding to “Object C” of object 304 is 98%, and the corresponding threshold value is 95%, therefore the comparison result indicates that object 303 and object 304 correspond to the same equipment type. The proportion of pixels that have identification information at the same pixel coordinates between the image area corresponding to “Object C2” of object 305 and the image area corresponding to “Object C2” of object 306 is 99%, and the corresponding threshold value is 96%, therefore the comparison result indicates that object 305 and object 306 correspond to the same equipment type. Finally, objects 303 and 304 belong to equipment type TO1, objects 305 and 306 belong to equipment type TO2, and the four objects 301 belong to equipment type TO3.

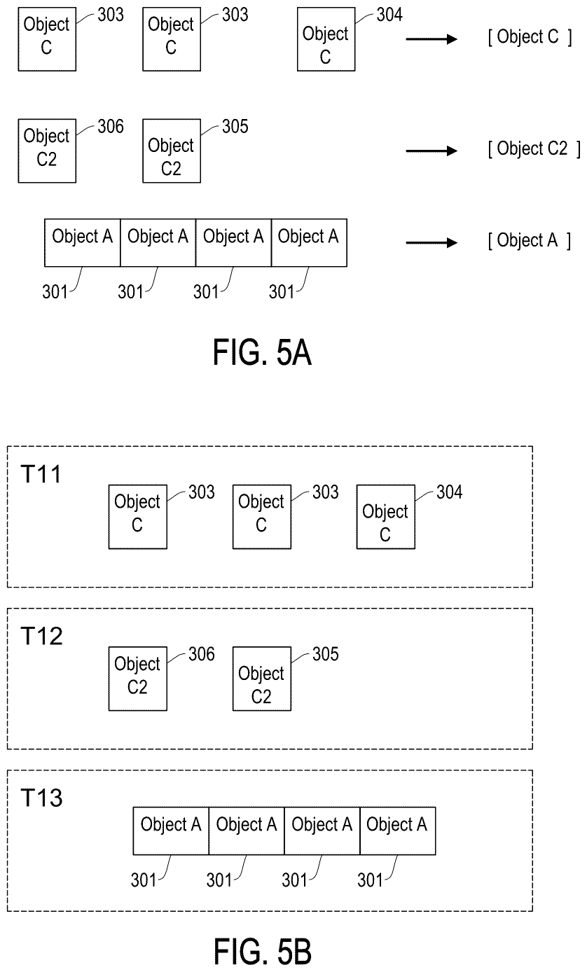

In one embodiment, the processor 130 may convert the identification information of the equipment object and the identification information of another equipment object into text form. For example, perform Optical Character Recognition (OCR) on the image area corresponding to the identification information in the floor plan image to obtain the identification information in text form. For example, FIG. 5A is a schematic diagram of an equipment candidate list according to an embodiment of the disclosure. Refer to FIG. 5A, the text form of the identification information for object 301 is “Object A”, the text form of the identification information for objects 303 and 304 is “Object C”, and the text form of the identification information for objects 305 and 306 is “Object C2”.

The processor 130 may compare the identification information in text form of the equipment object and another equipment object to generate a comparison result. In this case, the comparison result corresponds to word similarity. “Object C” and “Object C2” only have a numerical difference in the floor plan, but in fact belong to the same equipment type. However, as shown in FIG. 4B, the image similarity between object 303 and object 304 may be lower than the threshold value and thus be assigned or grouped into different equipment types TO1 and TO2.

The processor 130 may input the identification information in text form of two equipment objects into a classifier, and determine through the classifier whether the two pieces of identification information correspond to the same equipment type. The classifier is trained through a machine learning algorithm. The machine learning algorithm may be, for example, a word2vec word vector model, a word transformer, or Fast Sentence Embeddings, but is not limited to these. The processor 130 may use a text crawler to find words or phrases in a word database, and remove items such as punctuation marks, spaces, and non-words. In the training phase, the classifier uses the machine learning algorithm for word vector training. For example, word vector training with the Continuous Bag of Words (CBOW) model architecture. The trained classifier may map text to a multi-dimensional vector space. The distance between two words in the vector space may serve as word similarity.

For example, FIG. 5B is a schematic diagram of classification results according to an embodiment of the disclosure. Refer to FIG. 5A and FIG. 5B, if compared only by text, objects 303 and 304 belong to equipment type T11, objects 305 and 306 belong to equipment type T12, and the four objects 301 belong to equipment type T13.

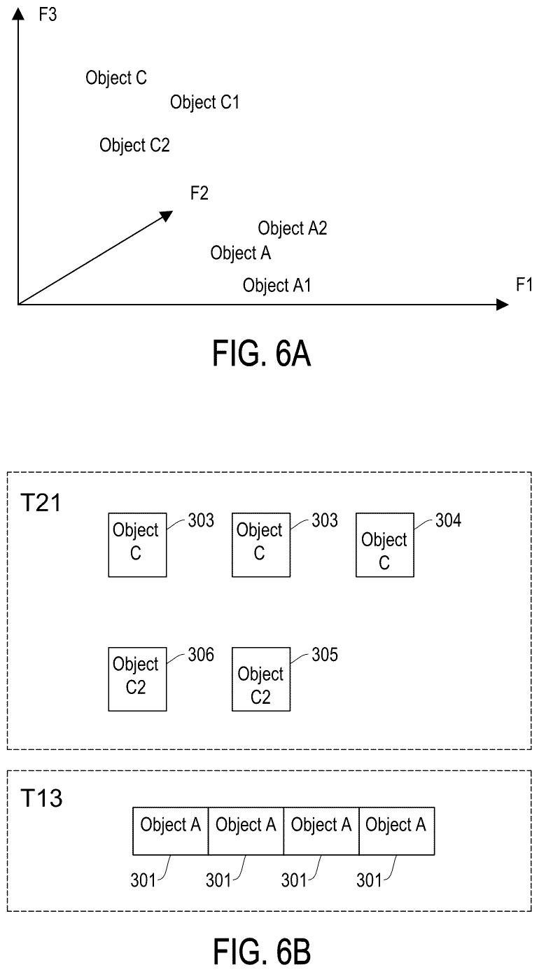

Next, FIG. 6A is a schematic diagram of a feature space according to an embodiment of the disclosure. Refer to FIG. 6A, assume this feature space is formed by three feature vectors F1, F2, F3 (corresponding to three axes/dimensions). The distances between “Object A”, “Object A1”, and “Object A2” in the feature space are closer (corresponding to higher word similarity), and the distances between “Object C”, “Object C1”, and “Object C2” in the feature space are closer. The distance between “Object A” and “Object C” in the feature space is farther (corresponding to lower word similarity).

FIG. 6B is a schematic diagram of classification results according to an embodiment of the disclosure. Refer to FIG. 5A, FIG. 5B and FIG. 6B, based on the distance relationship in FIG. 5B and through classifier analysis, objects 303, 304, 305 and 306 belong to equipment type T21 (corresponding to one candidate list), and the four objects 301 belong to equipment type T13 (corresponding to another candidate list).

In one embodiment, the processor 130 may compare the image area corresponding to a first equipment object in a candidate list with the image areas of other equipment objects in this candidate list respectively. By this, the number of recognitions and processing time may be reduced. Moreover, the processor 130 may select the one with the least number of words in the identification information as the representative of the identification information for the updated candidate list. Taking FIG. 6B as an example, the representative of the identification information for the candidate list of equipment type T21 is “Object C”. However, the comparison order and the determination of the identification information representative may still be adjusted according to actual requirements.

In one embodiment, the processor 130 may record the identification information in text form of the target object, its position in the plane configuration image (for example, pixel coordinates) and shape (for example, length and width values) as JSON data or other database data.

Refer to FIG. 2, the processor 130 adds corresponding three-dimensional objects in the three-dimensional space based on the position and shape of the target object in the plane configuration image (Step S220). Specifically, the position of the target object in the plane configuration image may be the pixel coordinates of the plane configuration image. The shape may be the (overall) length and/or width in the plane configuration image (for example, measured by the number of pixels).

In one embodiment, the processor 130 may name or number the target object. For example, using the identification information in text form for naming.

In one embodiment, the processor 130 may use preset geometric objects as three-dimensional objects. The preset geometric objects may be cuboids, cylinders, or conical bodies. The heights of preset geometric objects with different shapes may be the same or different. Taking FIG. 3 as an example, the corresponding preset geometric object for object 301 is a cuboid. The processor 130 may set the length and width of the cuboid to be the same as or corresponding to the length and width of object 301.

Next, the processor 130 may paste/add the preset geometric object of this target object at the corresponding position in the three-dimensional space based on the position of the target object in the plane configuration image. The three-dimensional space (also called three-dimensional structural model) corresponds to the three-dimensional space of the floor plan. The processor 130 may use a lookup table or conversion relationship/formula that maps the pixel coordinates of the plane configuration image to three-dimensional coordinates in the three-dimensional space to determine the corresponding position of the target object in the three-dimensional space.

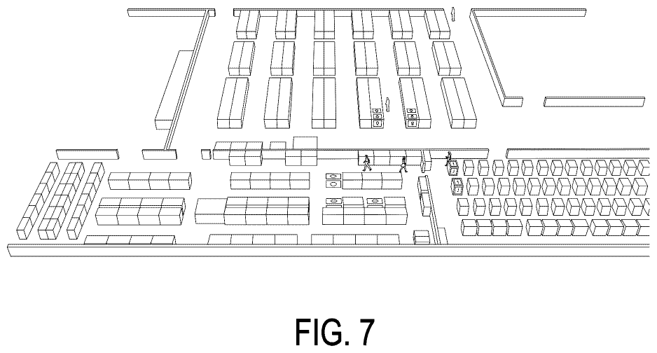

For example, FIG. 7 is a schematic diagram of a first virtual scene according to an embodiment of the present disclosure. Refer to FIG. 7, the first virtual scene is a simple three-dimensional scene model, and all target objects are presented as cuboids. The first virtual scene clearly presents the arrangement of objects, the flow of people, and possible obstruction situations.

In one embodiment, the processor 130 may retrieve one or more three-dimensional objects corresponding to the same identification information from a database. The database may store three-dimensional objects corresponding to multiple identification information. These three-dimensional objects may have more refined textures or appearances (compared to preset geometric objects). The processor 130 may compare the identification information in text form and search for three-dimensional objects with the same or corresponding identification information from the database. Moreover, the dimensions of the three-dimensional objects may correspond to the shape of the target object in the plane configuration image.

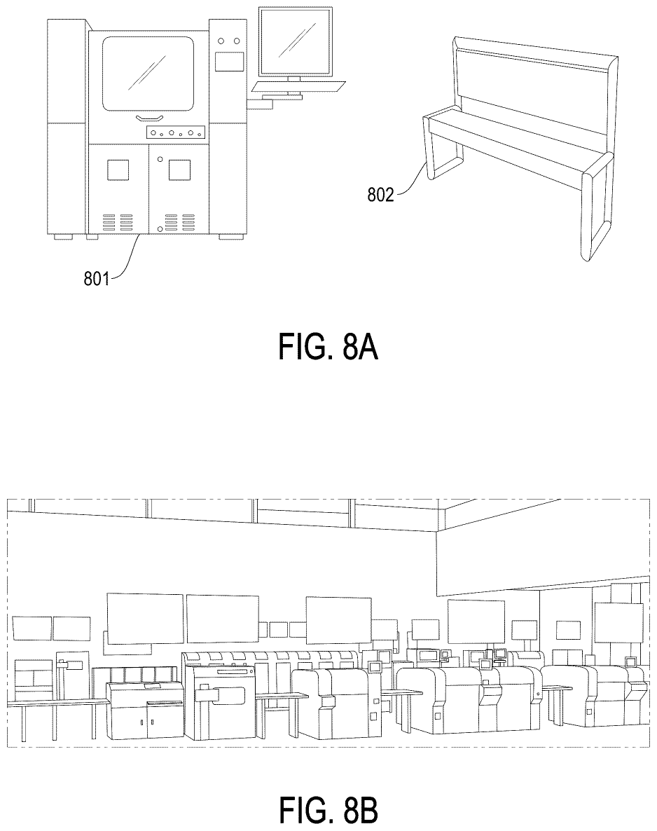

For example, FIG. 8A is a schematic diagram of three-dimensional objects 801, 802 according to an embodiment of the present disclosure. Refer to FIG. 8A, the three-dimensional object 801 corresponding to object 303 in FIG. 3 is a process equipment, and has more refined textures (for example, the display and partitions could be identified). The three-dimensional object 802 corresponding to object 301 in FIG. 3 is a bench, and has more refined textures (for example, the wooden boards and iron parts could be identified).

Next, the processor 130 may paste/add the corresponding three-dimensional object of this target object from the database at the corresponding position in the three-dimensional space based on the position of the target object in the plane configuration image. Similarly, the processor 130 may use a lookup table or conversion relationship/formula that maps the pixel coordinates of the plane configuration image to three-dimensional coordinates in the three-dimensional space to determine the corresponding position of the target object in the three-dimensional space.

For example, FIG. 8B is a schematic diagram of a second virtual scene according to an embodiment of the present disclosure. Refer to FIG. 8B, the second virtual scene is an advanced three-dimensional scene model, and the three-dimensional objects of all target objects have more refined textures or appearances. The second virtual scene clearly presents the arrangement of objects, the flow of people, and possible obstruction situations, and even allows direct difference of object types or equipment types by observing the appearance of the three-dimensional objects.

In one embodiment, the construction of the above-mentioned three-dimensional model may be realized in a three-dimensional design or simulation platform (for example, Omniverse platform). For instance, by inputting compatible JSON data or other database data (recording the identification information in text form of the target objects and their positions and shapes in the plane configuration image) into the three-dimensional design or simulation platform to generate a corresponding three-dimensional model.

In summary, in the three-dimensional scene construction method and three-dimensional scene construction device of the embodiments of the present disclosure, a three-dimensional scene with corresponding dimensions is generated based on the plane configuration image. By this, the efficiency and cost of model construction may be improved, and the hardware requirements for applications can be lowered.

In some application scenarios, users previously had to manually drag three-dimensional equipment files onto the execution screen of software for placement, which was not only time-consuming and labor-intensive, but also might result in inaccurate positioning. The embodiments of the present disclosure can accurately place three-dimensional equipment files in the correct positions, solving the problem of distorted simulation results caused by the inaccurate placement of users when dragging three-dimensional equipment files into the three-dimensional space in the past. Moreover, in some application environments, there may be thousands or tens of thousands of objects, and the time spent on manually placing three-dimensional objects is unimaginable, but the embodiments of the present disclosure can significantly reduce the time for model construction.

It would be apparent to those skilled in the art that various modifications and variations could be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A three-dimensional scene building method, implemented through a processor, and the three-dimensional scene building method comprising:
identifying at least one target object in a plane configuration image, wherein the plane configuration image corresponds to a floor plan with contours of the at least one target object; and
adding at least one corresponding three-dimensional object in a three-dimensional space based on the position and shape of the at least one target object in the plane configuration image.

2. The three-dimensional scene building method as claimed in claim 1, wherein identifying the at least one target object in the plane configuration image comprises:
identifying the at least one target object based on the shape of the at least one target object.

3. The three-dimensional scene building method as claimed in claim 2, wherein the at least one target object includes a structural object, the shape of the structural object corresponds to length and width thereof, and identifying the at least one target object based on the shape of the at least one target object comprises:
deciding that the length of the structural object is greater than a lower length threshold; and
deciding that the width of the structural object is within a first width range.

4. The three-dimensional scene building method as claimed in claim 1, wherein the at least one target object includes a structural object, and identifying the at least one target object in the plane configuration image comprises:
performing a binarization process on the plane configuration image, wherein the binarization process uses a classification threshold value defined based on the grayscale value of the structural object;
selecting the structural object from the plane configuration image that has undergone the binarization process.

5. The three-dimensional scene building method as claimed in claim 2, wherein the at least one target object includes an equipment object, the shape of the equipment object corresponds to length and width thereof, and identifying the at least one target object based on the shape of the at least one target object comprises:
deciding that the length of the equipment object is within a length range; and
deciding that the width of the equipment object is within a second width range.

6. The three-dimensional scene building method as claimed in claim 1, wherein the at least one target object includes an equipment object, the equipment object further has identification information thereof in the plane configuration image, and identifying the at least one target object in the plane configuration image comprises:
comparing the identification information of the equipment object with the identification information of another equipment object to generate a comparison result; and
deciding an equipment type corresponding to the equipment object and the another equipment object based on the comparison result.

7. The three-dimensional scene building method as claimed in claim 6, wherein comparing the identification information of the equipment object with the identification information of the another equipment object comprises:
converting the identification information of the equipment object and the identification information of the another equipment object into a text form; and
comparing the identification information in text form of the equipment object and the another equipment object to generate the comparison result, wherein the comparison result corresponds to a word similarity.

8. The three-dimensional scene building method as claimed in claim 6, wherein comparing the identification information of the equipment object with the identification information of the another equipment object comprises:
comparing the identification information of the equipment object and the another equipment object in the plane configuration image to generate the comparison result, wherein the comparison result corresponds to an image similarity.

9. The three-dimensional scene building method as claimed in claim 1, wherein adding the corresponding at least one three-dimensional object comprises:
setting a default geometric object as one of the three-dimensional objects; or
obtaining the at least one three-dimensional object corresponding to the same identification information from a database.

10. The three-dimensional scene building method as claimed in claim 1, further comprising:
converting an engineering drawing into the plane configuration image, wherein the engineering drawing is generated by adding shapes corresponding to at least one target object to the floor plan.

11. A three-dimensional scene building device, comprising:
a memory, storing a program code; and
a processor, coupled to the memory, loading the program code and executing:
identifying at least one target object in a plane configuration image, wherein the plane configuration image corresponds to a floor plan having contours of the at least one target object; and
adding corresponding at least one three-dimensional object in a three-dimensional space based on the position and shape of the at least one target object in the plane configuration image.

12. The three-dimensional scene building device as claimed in claim 11, wherein the processor further executes:
identifying the at least one target object based on the shape of the at least one target object.

13. The three-dimensional scene building device as claimed in claim 12, wherein the at least one target object comprises a structural object, the shape of the structural object corresponds to length and width thereof, and the processor further executes:
deciding that the length of the structural object is greater than a lower length limit; and
deciding that the width of the structural object is within a first width range.

14. The three-dimensional scene building device as claimed in claim 11, wherein the at least one target object comprises a structural object, and the processor further executes:
performing a binarization process on the plane configuration image, wherein the binarization process uses a classification threshold value defined based on the grayscale value of the structural object;
selecting the structural object from the plane configuration image that has undergone the binarization process.

15. The three-dimensional scene building device as claimed in claim 12, wherein the at least one target object comprises an equipment object, the shape of the equipment object corresponds to length and width thereof, and the processor further executes:
deciding that the length of the equipment object is within a length range; and
deciding that the width of the equipment object is within a second width range.

16. The three-dimensional scene building device as claimed in claim 11, wherein the at least one target object comprises an equipment object, the equipment object further has identification information thereof in the plane configuration image, and the processor further executes:
comparing the identification information of the equipment object with the identification information of another equipment object to generate a comparison result; and
deciding an equipment type corresponding to the equipment object and the other equipment object based on the comparison result.

17. The three-dimensional scene building device as claimed in claim 16, wherein the processor further executes:
Converting the identification information of the equipment object and the identification information of the other equipment object into a text form; and
comparing the identification information in text form of the equipment object and the other equipment object to generate the comparison result, wherein the comparison result corresponds to a word similarity.

18. The three-dimensional scene building device as claimed in claim 16, wherein the processor further executes:
comparing the identification information of the equipment object and the other equipment object in the plane configuration image to generate the comparison result, wherein the comparison result corresponds to an image similarity.

19. The three-dimensional scene building device as claimed in claim 11, wherein the processor further executes:
setting a default geometric object as the three-dimensional object; or
retrieving the at least one three-dimensional object corresponding to the same identification information from a database.

20. The three-dimensional scene building device as claimed in claim 11, wherein the processor further executes:
converting an engineering drawing into the plane configuration image, wherein the engineering drawing is generated by adding shapes corresponding to at least one target object to the floor plan.
